(19) United States
(12) Patent Application Publication
(10) Pub. No.: US 2026/0082929 A1
(43) Pub. Date: Mar. 19, 2026

(54) PARASITIC CAPACITANCE GROUNDING STRUCTURE FOR HYBRID BONDING

(71) Applicant: International Business Machines Corporation, Armonk, NY (US)

(72) Inventors: Nicholas Latham, Albany, NY (US); Kishan Jayanand, Albany, NY (US); Viswas Purohit, East Amherst, NY (US); Nicholas Alexander POLOMOFF, Hopewell Junction, NY (US); Junwon Han, Loudonville, NY (US); Aakrati Jain, Albany, NY (US); Sathyanarayanan Raghavan, Ballston Lake, NY (US); Mary McGahay, Troy, NY (US)

(21) Appl. No.: 18/888,133

(22) Filed: Sep. 17, 2024

(51) Int. Cl. H01L 23/62; H01L 23/00; H01L 23/498

(52) U.S. Cl. CPC H10W 42/80; H10W 70/65; H10W 72/952; H10W 72/967; H10W 80/312; H10W 80/327; H10W 90/794

(57) ABSTRACT

An upper semiconductor build has an upper build dielectric; at least two upper build electrical signal contact bonding pads; at least one upper build dummy contact bonding pad; an upper build ground network electrically coupled to the at least two upper build electrical signal contact bonding pads; and an upper build anti-fuse dielectric between the upper build ground network and the upper build dummy contact bonding pad. A lower semiconductor build has a lower build dielectric; at least two lower build electrical signal contact bonding pads; at least one lower build dummy contact bonding pad; a lower build ground network; and a lower build anti-fuse dielectric between the lower build ground network and the lower build dummy contact bonding pad. The two builds are hybrid bonded to each other. When excess charge builds up, the anti-fuse dielectrics are blown and conduct the excess charge to ground.

### BACKGROUND

The present invention relates generally to the electrical, electronic and computer arts and, more particularly, to hybrid bonding, and the like.

In hybrid bonding, a permanent bond combines a dielectric bond (e.g., SiOₓ) with embedded metal (e.g., Cu) to form interconnections. Two semiconductor builds are joined (e.g., two individual wafers that are built separately). They require a “pristine” surface (smooth and flat, possibly with some recesses), more so than traditional chemical-mechanical planarization (CMP). The two builds are purposely designed to align. The term “hybrid” refers to the presence of both copper and dielectric. A bond that uses dielectric alone is referred to as fusion bonding (oxide to oxide). Hybrid bonding uses metal to metal connections for the copper. The two builds are brought together and a small heat treatment/annealing process is carried out. The oxides bond together and the metals “anneal,” or almost melt, together, thus fusing the interface into a single bonded part (in some instances, seamlessly; i.e., the interface line disappears).

In current approaches to hybrid bonding, as the hybrid bond pads are moved closer for scaling purposes, there is a possibility of parasitic charge buildup in the dielectric material (the adjacent hybrid bond pads act as capacitor plates and the charges build up when there are voltage differences between adjacent pads due to the passage of electrical signals).

### BRIEF SUMMARY

Principles of the invention provide techniques for parasitic capacitance grounding structure for hybrid bonding. In one aspect, an exemplary structure includes an upper semiconductor build having: an upper build dielectric; at least two upper build electrical signal contact bonding pads, located within the upper build dielectric, and having exposed upper build electrical signal contact bonding pad surfaces; and at least one upper build dummy contact bonding pad, located within the upper build dielectric, and having an exposed upper build dummy contact bonding pad surface. The upper semiconductor build further has an upper build ground network, located within the upper build dielectric, electrically coupled to the at least two upper build electrical signal contact bonding pads; and an upper build anti-fuse dielectric between the upper build ground network and the upper build dummy contact bonding pad. The structure further has a lower semiconductor build having: a lower build dielectric; at least two lower build electrical signal contact bonding pads, located within the lower build dielectric, and having exposed lower build electrical signal contact bonding pad surfaces; and at least one lower build dummy contact bonding pad, located within the lower build dielectric, and having an exposed lower build dummy contact bonding pad surface. The lower semiconductor build further has a lower build ground network, located within the lower build dielectric, electrically coupled to the at least two lower build electrical signal contact bonding pads; and a lower build anti-fuse dielectric between the lower build ground network and the lower build dummy contact bonding pad. The lower build dielectric is hybrid bonded to the upper build dielectric; the at least two lower build electrical signal contact bonding pads are respectively hybrid bonded to the at least two upper build electrical signal contact bonding pads; and the at least one lower build dummy contact bonding pad is hybrid bonded to the at least one upper build dummy contact bonding pad.

In another aspect, an exemplary method includes providing a structure of the kind just described; operating the structure until excess charge builds up in the upper build dielectric and the lower build dielectric to blow the upper and lower build anti-fuse dielectrics; and conducting the excess charge to ground through the blown upper and lower build anti-fuse dielectrics.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments provide one or more of:
grounds parasitic capacitance, preventing the buildup of unwanted charge on the chip(s) or other semiconductor builds and enhancing performance;
use of conductive metal allows for selection based on specific conductivity and shielding requirements;
can be fabricated to match various sizes of semiconductor chips, from tiny microchips to large integrated circuits;
allows incorporation into current semiconductor manufacturing processes without significant alterations;
does not interfere with the standard functionalities of the chip(s) or other semiconductor build(s);
safeguards the input/output (I/O) against disturbances, increasing the overall reliability and lifespan of the device, and/or reducing potential maintenance or replacement costs for end-users; and
the chosen conductive metal can facilitate dissipation of charge build up, reduce potential for dielectric breakdown due to capacitance build up, reduce ion migration through the dielectric, enhance heat dissipation, and help to avoid potential thermal issues arising from capacitance.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1 and 2 are side cross-sectional and plan views of a structure according to aspects of the invention;

FIGS. 3-12 show exemplary steps in a device process flow, according to an aspect of the invention;

FIGS. 13-22 show exemplary steps in a carrier process flow, according to an aspect of the invention;

FIG. 23 shows aspects of grounding network formation, according to an aspect of the invention; and

FIG. 24 show a table with exemplary material selection rules, according to an aspect of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

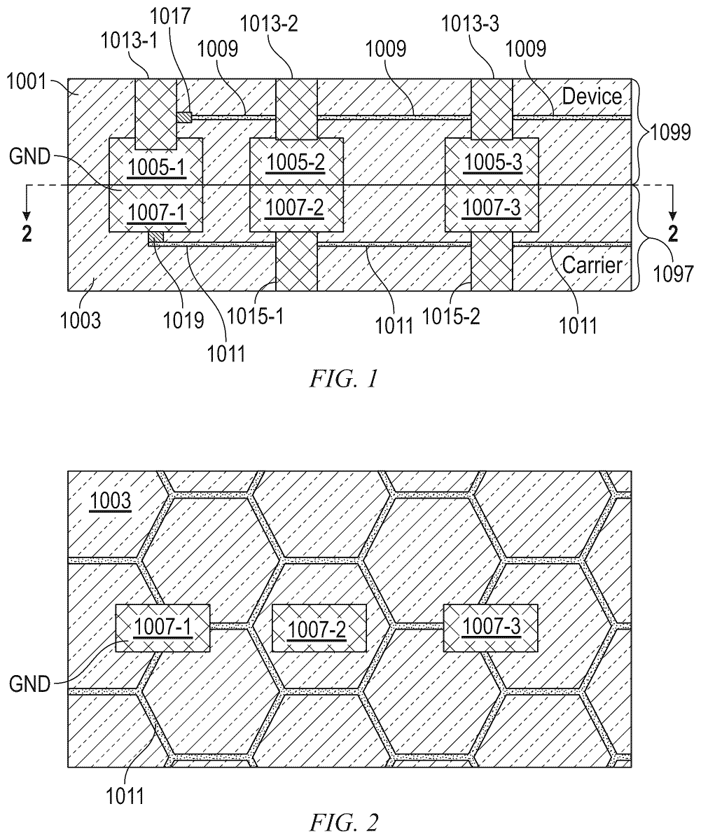

One or more embodiments provide a parasitic capacitance grounding structure for hybrid bonding. Refer to FIGS. 1 and 2. FIG. 2 is at line ii-ii in FIG. 1. Device 1099 is hybrid bonded to carrier 1097. Note the device dielectric 1001, carrier dielectric 1003; the device hybrid bonding pads 1005-1, 1005-2, and 1005-3; and the carrier hybrid bonding pads 1007-1, 1007-2, and 1007-3. Further note the device parasitic capacitance reduction structure 1009 and the carrier parasitic capacitance reduction structure 1011. The carrier parasitic capacitance reduction structure 1011 is visible in FIG. 2 because in the non-limiting example of FIGS. 1 and 2, the carrier dielectric 1003 is transparent. In one or more embodiments, however, the device parasitic capacitance reduction structure 1009 and the carrier parasitic capacitance reduction structure 1011 are not present at the hybrid bond interface between the device and the carrier, but are buried in the dielectric. Finally, note the device vias 1013-1, 1013-2, and 1013-3 connected to the device hybrid bonding pads; the carrier vias 1015-1 and 1015-2 connected to the carrier hybrid bonding pads; and the anti-fuse dielectric 1017 and 1019. In the non-limiting example of FIGS. 1 and 2, the bond pads 1007-1, 1005-1 and via 1013-1 form a ground path, while the via 1015-1, bond pads 1007-2, 1005-2 and via 1013-2 form a first signal path and the via 1015-2, bond pads 1007-3, 1005-3 and via 1013-3 form a second signal path.

In one or more embodiments, the networks 1017, 1019 take parasitic charges in the dielectric material 1001, 1003 out of the device and the carrier. Advantageously, one or more embodiments are scalable because hybrid bonding can be scaled. In the non-limiting example of FIGS. 1 and 2, the networks 1017, 1019 are hexagonal in shape but they can be any suitable shape such as octagonal, square, round, and the like. In one or more embodiments, increased resistance is provided by the anti-fuse material 1017, 1019 so as not to interrupt the charge flow (current) through the hybrid bonding contact, which is moving, for example, from the device 1099 to the carrier wafer 1097. In one or more embodiments, good conduction is desired through the non-dummy actual hybrid bond pads 1005-2/1007-2 and 1005-3/1007-3.

Further regarding the parasitic capacitance, in one or more embodiments, signals pass from the device 1099 to the carrier 1097. There is a general desire to move the hybrid bond pads closer as geometry scales down. Because of the voltage difference between two adjacent hybrid bond pads, they function as capacitor plates, which is not desired. This causes charges to build up in the dielectric between the adjacent pads. Without use of aspects of the invention, it is possible to have an undesirable short between adjacent hybrid bond pads. One or more embodiments advantageously get rid of undesirable parasitic charges. The networks 1017, 1019 can connect to vias over/under the hybrid bond pads, but a short does not occur because the conductive metal used to form the networks 1009, 1011 is less conductive than the conductive metals that forms the pads and vias. Charge could potentially leak into the ground pads if the resistance is not high enough (thus, one or more embodiments use anti-fuse material 1017, 1019). In one or more embodiments, the anti-fuse material 1017, 1019 keeps the networks 1009, 1011 from interfering with signals through the bond pads, so that the networks 1009, 1011 only collect parasitic charges. At some point, when sufficient parasitic charge builds up, the anti-fuse material 1017, 1019 “blows” and the ground pathway becomes conductive. The anti-fuse material 1017, 1019 could be “one time” or reusable (for reusable, some materials are available that have reversible dielectric breakdown which are suitable) depending on the material and the desired application.

Thus, still referring to FIGS. 1 and 2, in one or more embodiments, an exemplary structure has a contact 1005-1, 1005-2, 1005-3, 1007-1, 1007-2, 1007-3 at the hybrid bond interface surrounded by a different, less conductive metal 1009, 1011 than the contact. Dummy contacts 1005-1, 1007-1 are provided; they are made of the same conductive metal as the conductive contacts 1005-2, 1005-3, 1007-2, 1007-3, and they connect to ground (GND). One or more embodiments are scalable to smaller feature sizes (e.g., <2 μm pitch). In some instances, a conductive network of metal 1009, 1011 is connected to the dummy contacts 1005-1, 1007-1 and surrounds the conductive contacts 1005-2, 1005-3, 1007-2, 1007-3 to ground parasitic capacitance (thus forming a conductive barrier). The ground network surrounding the conductive contacts can, as noted, be of any suitable shape (hexagonal, octagonal, square, round, and the like). In one or more embodiments, the grounding network is joined to ground by anti-fuse material 1017, 1019 to increase resistance.

It is worth noting that charge buildup increases temperature; thus, removing stray changes is also thermally beneficial.

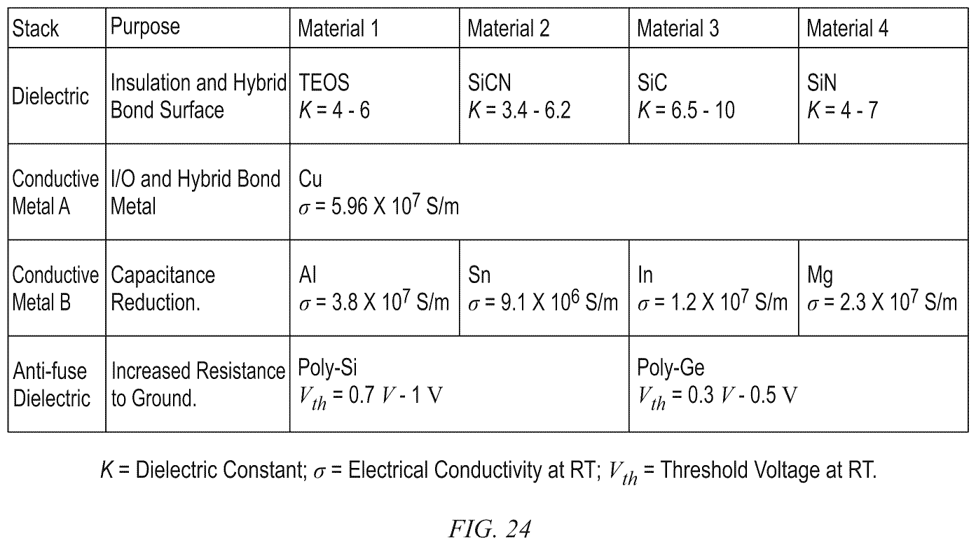

FIG. 24 shows exemplary materials selection rules. “Conductive Metal A” refers to the metal for the pads and vias while “Conductive Metal B” refers to the metal for the networks 1009, 1011. RT refers to room temperature and TEOS refers to Tetraethyl orthosilicate, formally named tetraethoxysilane. The listed anti-fuse materials are not limited to one-time; they have reversible dielectric properties. Non-limiting examples of one-time materials include amorphous Si (a-Si), porous SiO₂, polyimides, and the like. The threshold voltage Vₜₕ is the voltage that must be exceeded to break down the dielectric.

It is worth noting that unlike certain prior art approaches using a standard hybrid bonding process flow for joining two dies, one or more embodiments include formation of a conductive network buried in the dielectric below the hybrid bonding interface to reduce parasitic capacitance. One or more structural embodiments capture stray charges using a metal network or the like, and sending these stray charges through an anti-fuse connected to a ground (GND) terminal.

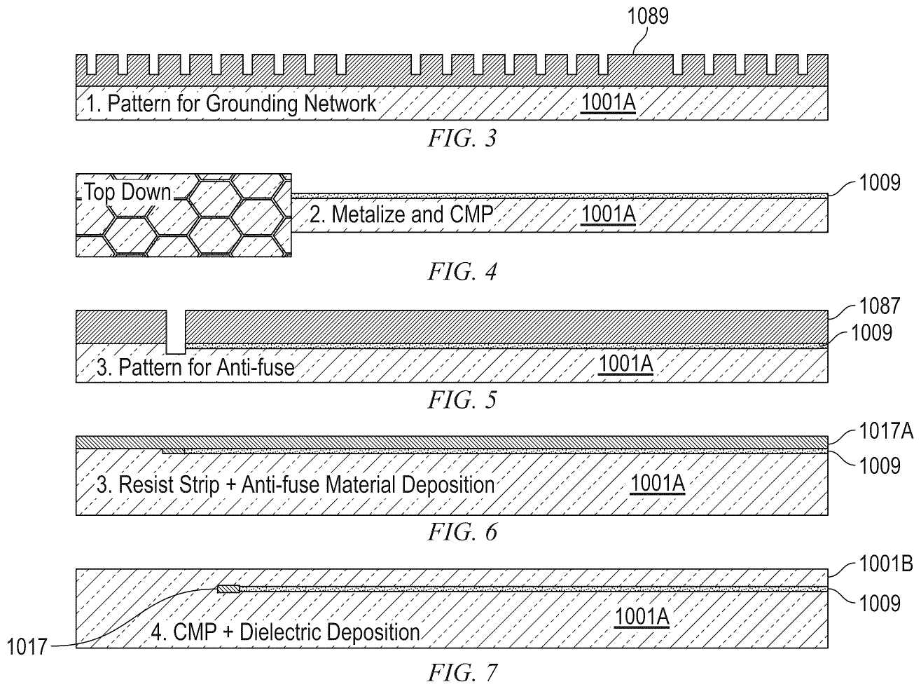

FIGS. 3-12 show exemplary steps in a device process flow for forming the device 1099. In FIG. 3, start with device dielectric 1001A and pattern same for the grounding network 1009. Note that the dielectric 1001A can be on some kind of carrier, omitted to avoid clutter. Note the patterned photoresist 1089. FIG. 4 shows the structure of FIG. 3 after metallizing using the patterned photoresist, stripping the photoresist, and carrying out chemical-mechanical planarization (CMP) or the like to form the network 1009. FIG. 5 shows the structure of FIG. 4 after depositing photoresist 1087 and patterning same in preparation to form the anti-fuse structures. FIG. 6 shows the structure of FIG. 5 after stripping photoresist 1087 and depositing anti-fuse material 1017A. Note that for illustrative convenience, the drawings are not necessarily to scale or proportion; for example, layer 1001A would typically be the same thickness between FIGS. 5 and 6. FIG. 7 shows the structure of FIG. 6 after carrying out CMP to remove excess material 1017A, leaving anti-fuse material 1017, and after depositing additional dielectric 1001B.

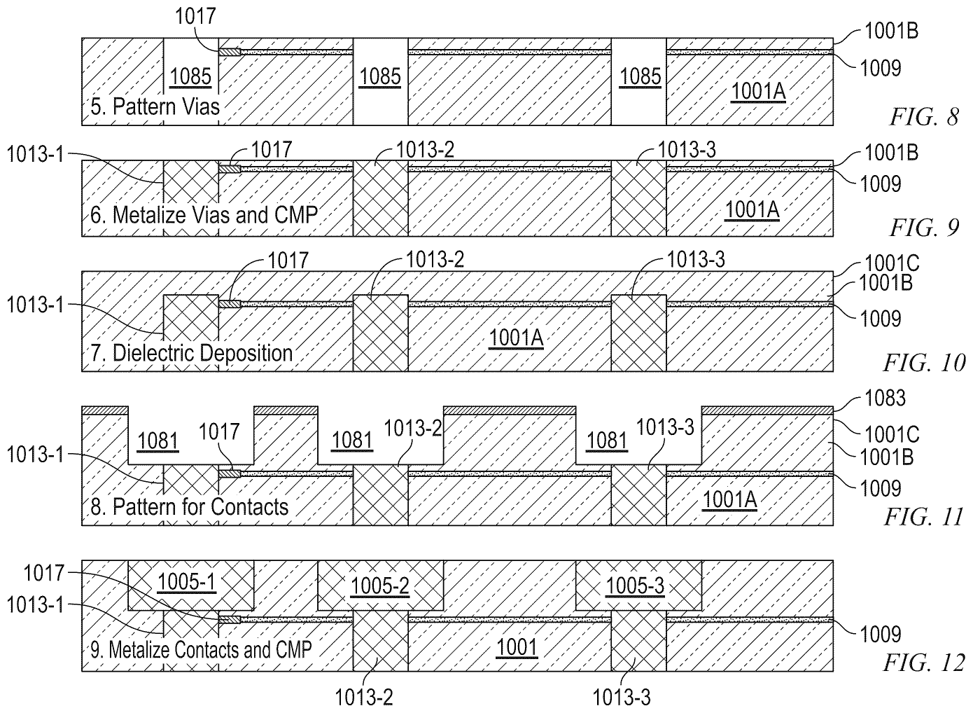

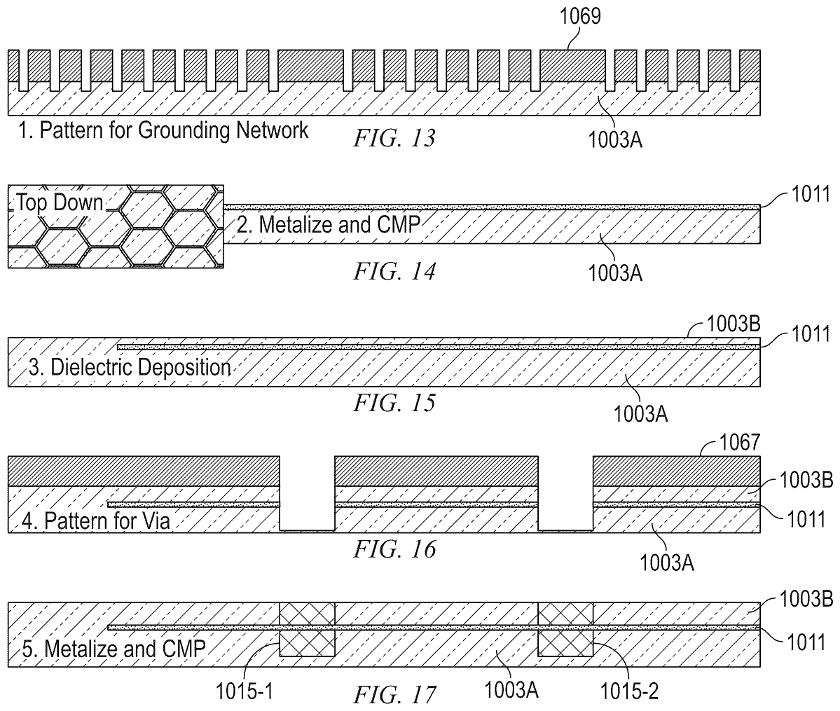

FIG. 8 shows the structure of FIG. 7 after patterning cavities 1085 for the vias. Again, note that for illustrative convenience, the drawings are not necessarily to scale or proportion; for example, layer 1001A would typically be the same thickness between FIGS. 7 and 8. FIG. 9 shows the structure of FIG. 8 after metallizing the cavities 1085 and carrying out CMP to form the vias 1013-1, 1013-2, 1013-3. FIG. 10 shows the structure of FIG. 9 after depositing additional dielectric 1001C. FIG. 11 shows the structure of FIG. 10 after depositing photoresist 1083 and patterning same in preparation to form the contacts in the resultant cavities 1081. FIG. 12 shows the final structure after metallizing the contacts and carrying out CMP. The “total” dielectric is designated as 1001 as in FIG. 1. The orientation in FIG. 12 is “flipped” with respect to FIG. 1.

FIGS. 13-22 show exemplary steps in a carrier process flow for forming the carrier 1097. In FIG. 13, start with carrier dielectric 1003A and pattern same for the grounding network 1011. Note that the dielectric 1003A can be on some kind of carrier, omitted to avoid clutter. Note the patterned photoresist 1069. FIG. 14 shows the structure of FIG. 13 after metallizing using the patterned photoresist, stripping the photoresist, and carrying out chemical-mechanical planarization (CMP) or the like to form the network 1011. FIG. 15 shows the structure of FIG. 14 after depositing additional dielectric 1003B. FIG. 16 shows the structure of FIG. 15 after depositing photoresist 1067 and patterning same in preparation to form the vias. Again, note that for illustrative convenience, the drawings are not necessarily to scale or proportion; for example, layer 1003B would typically be the same thickness between FIGS. 14 and 15. FIG. 17 shows the structure of FIG. 16 after stripping photoresist 1067, metallizing to form the vias 1015-1, 1015-2, and carrying out CMP.

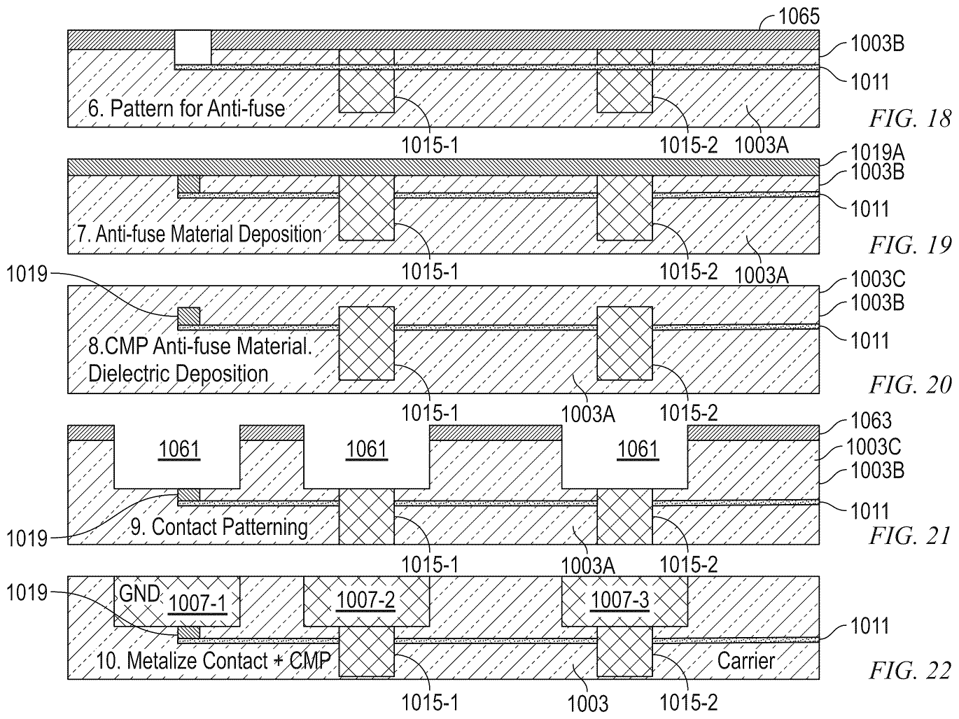

FIG. 18 shows the structure of FIG. 17 after depositing photoresist 1065 and patterning same in preparation to form the anti-fuse. FIG. 19 shows the structure of FIG. 18 after stripping the photoresist 1065 and depositing anti-fuse material 1019A. FIG. 20 shows the structure of FIG. 19 after carrying out CMP to remove excess material 1019A, leaving anti-fuse material 1019, and after depositing additional dielectric 1003C. FIG. 21 shows the structure of FIG. 20 after patterning cavities 1061 for the contacts. Note the patterned photoresist 1063. FIG. 22 shows the final structure after metallizing the cavities 1061 and carrying out CMP. The “total” dielectric is designated as 1003 as in FIG. 1. Again, note that for illustrative convenience, the drawings are not necessarily to scale or proportion; for example, layers 1003A, 1003B, and 1003C would typically be the same thickness between steps that do not involve removal of material.

Generally, standard photolithography, deposition, etching, and metallization techniques can be employed in FIGS. 3-22. In the final structure for both the device and carrier, note vias in contact with the ground network.

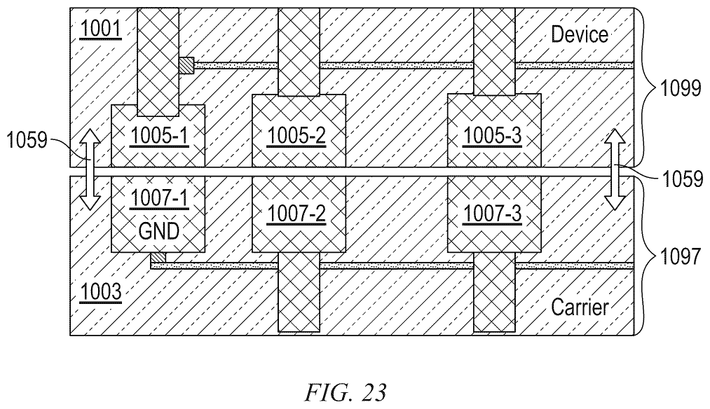

FIG. 23 shows aspects of alignment of the pads 1005-1, 1005-2, 1005-3 with the pads 1007-1, 1007-2, and 1007-3 and hybrid bonding of the pads and the dielectrics 1001, 1003, resulting in formation of the grounding network. The positioning and hybrid bonding are symbolized by the block arrows 1059.

Given the discussion thus far, it will be appreciated that, in general terms, an exemplary structure includes an upper semiconductor build 1099 having an upper build dielectric 1001; at least two upper build electrical signal contact bonding pads 1005-2, 1005-3, located within the upper build dielectric, and having exposed upper build electrical signal contact bonding pad surfaces (i.e., interface where the upper and lower builds come together for bonding); and at least one upper build dummy contact bonding pad 1005-1 (i.e., one or more), located within the upper build dielectric, and having an exposed upper build dummy contact bonding pad surface (i.e., interface where the upper and lower builds come together for bonding). The upper semiconductor build also includes an upper build ground network 1009, located within the upper build dielectric, electrically coupled to the at least two upper build electrical signal contact bonding pads; and an upper build anti-fuse dielectric 1017 between the upper build ground network and the upper build dummy contact bonding pad.

The exemplary structure further includes a lower semiconductor build 1097 having: a lower build dielectric 1003; at least two lower build electrical signal contact bonding pads 1007-2, 1007-3, located within the lower build dielectric, and having exposed lower build electrical signal contact bonding pad surfaces (i.e., interface where the upper and lower builds come together for bonding); and at least one lower build dummy contact bonding pad 1007-1 (i.e., one or more), located within the lower build dielectric, and having an exposed lower build dummy contact bonding pad surface (i.e., interface where the upper and lower builds come together for bonding). The lower semiconductor build also includes a lower build ground network 1011, located within the lower build dielectric, electrically coupled to the at least two lower build electrical signal contact bonding pads; and a lower build anti-fuse dielectric 1019 between the lower build ground network and the lower build dummy contact bonding pad.

The lower build dielectric is hybrid bonded to the upper build dielectric. The at least two lower build electrical signal contact bonding pads are respectively hybrid bonded to the at least two upper build electrical signal contact bonding pads. The at least one lower build dummy contact bonding pad is hybrid bonded to the at least one upper build dummy contact bonding pad.

In one or more embodiments, the lower build ground network is made from metal having a lower electrical conductivity than the lower build electrical signal contact bonding pads and the lower build dummy contact bonding pad; and the upper build ground network is made from metal having a lower electrical conductivity than the upper build electrical signal contact bonding pads and the upper build dummy contact bonding pad.

Some instances further include at least two upper build electrical signal contact vias 1013-2, 1013-3, located within the upper build dielectric, and respectively coupled to the at least two upper build electrical signal contact bonding pads; and at least one upper build dummy contact via 1013-1, located within the upper build dielectric, and coupled to the at least one upper build dummy contact bonding pad. The upper build anti-fuse dielectric is between the upper build ground network and the upper build dummy contact via, and the upper build electrical signal contact bonding pads are coupled to the upper build ground network through the upper build electrical signal contact vias. Also included are at least two lower build electrical signal contact vias 1015-1, 1015-2, located within the lower build dielectric, and respectively coupled to the at least two lower build electrical signal contact bonding pads, where the lower build anti-fuse dielectric is directly between the lower build ground network and the lower build dummy contact bonding pad, and where the lower build electrical signal contact bonding pads are coupled to the lower build ground network through the lower build electrical signal contact vias.

In a non-limiting example, the upper and lower build ground networks include a hexagonal mesh.

The upper and lower build dielectrics can include, for example, TEOS, SiCN, SiC, or SiN.

In one or more embodiments, the at least two upper build electrical signal contact bonding pads, the at least one upper build dummy contact bonding pad, the at least two upper build electrical signal contact vias, the at least one upper build dummy contact via, the at least two lower build electrical signal contact bonding pads, the at least one lower build dummy contact bonding pad, and the at least two lower build electrical signal contact vias are formed from a first metal; and the metal from which the lower build ground network is made and the metal from which the upper build ground network is made include a same, second metal.

The first metal can include, for example, copper.

The second metal can include, for example, aluminum, tin, indium, or magnesium.

The upper build anti-fuse dielectric and the lower build anti-fuse dielectric can include, for example, poly-silicon or poly-germanium.

As noted elsewhere, the upper build anti-fuse dielectric and the lower build anti-fuse dielectric can include a one-time material or a reusable material.

In some cases, the at least two upper build electrical signal contact vias and the at least two lower build electrical signal contact vias have a pitch (on-center distance) of less than 2 micrometers (μm).

In one or more embodiments, the anti-fuse is configured to “blow” and become conductive when enough charge accumulates. This can be determined, for example, by using coupled-field (e.g., electromagnetic and thermal) finite element analysis.

In another aspect, an exemplary method includes providing a structure as described above; operating the structure until excess charge builds up in the upper build dielectric and the lower build dielectric to blow the upper and lower build anti-fuse dielectrics; and conducting the excess charge to ground through the blown upper and lower build anti-fuse dielectrics.

It is worth noting that hybrid bonding refers to a three-dimensional (3D) packaging technique to connect semiconductor builds. Hybrid bonding forms connections of semiconductor structures through metal pads which are embedded in a dielectric layer at a bond interface on each semiconductor structure that is being bonded. Materials for the dielectric layer at the bond interface can include, but are not necessarily limited to, tetraethyl orthosilicate (TEOS), silicon dioxide (SiO₂), silicon carbon nitride (SiCN), and/or carbon-doped silicon oxide (SiCOH). Materials for the metal pads embedded in the dielectric surfaces most commonly include, but are not necessarily limited to, copper (Cu). As part of the hybrid bonding process, the aforementioned dielectric materials go through an activation process, including but not necessarily limited to, O₂/N₂ plasma activation followed by a de-ionized water rinsing. Such activation process creates surface dangling bonds through hydroxylation of dielectric surfaces. The hybrid bonding process includes alignment to control the overlay of the metal pads and to ensure electrical continuity between the semiconductor builds undergoing the hybrid bonding process; mating of dielectric/metal pad surfaces; and annealing under a set pressure. The anneal process of the mated semiconductor builds ensures formation of covalent bonds between the dangling bonds across the dielectric surfaces of opposing semiconductor builds, as well as reflow (melting and joining) of the Cu metal pads between the surfaces of the opposing semiconductor builds, to ensure electrical conductivity. The covalent bonds formed between the dielectric surfaces, and the joining of the Cu pads as a result of the reflow process, ensure that hybrid bonding joins two semiconductor builds and also ensures that there is electrical continuity between them.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A structure comprising:
an upper semiconductor build having:
an upper build dielectric;
at least two upper build electrical signal contact bonding pads, located within the upper build dielectric, and having exposed upper build electrical signal contact bonding pad surfaces;
at least one upper build dummy contact bonding pad, located within the upper build dielectric, and having an exposed upper build dummy contact bonding pad surface;
an upper build ground network, located within the upper build dielectric, electrically coupled to the at least two upper build electrical signal contact bonding pads; and
an upper build anti-fuse dielectric between the upper build ground network and the upper build dummy contact bonding pad; and
a lower semiconductor build having:
a lower build dielectric;
at least two lower build electrical signal contact bonding pads, located within the lower build dielectric, and having exposed lower build electrical signal contact bonding pad surfaces;
at least one lower build dummy contact bonding pad, located within the lower build dielectric, and having an exposed lower build dummy contact bonding pad surface;
a lower build ground network, located within the lower build dielectric, electrically coupled to the at least two lower build electrical signal contact bonding pads; and
a lower build anti-fuse dielectric between the lower build ground network and the lower build dummy contact bonding pad;
wherein:
the lower build dielectric is hybrid bonded to the upper build dielectric;
the at least two lower build electrical signal contact bonding pads are respectively hybrid bonded to the at least two upper build electrical signal contact bonding pads; and
the at least one lower build dummy contact bonding pad is hybrid bonded to the at least one upper build dummy contact bonding pad.

2. The structure of claim 1, wherein:
the lower build ground network is made from metal having a lower electrical conductivity than the lower build electrical signal contact bonding pads and the lower build dummy contact bonding pad; and
the upper build ground network is made from metal having a lower electrical conductivity than the upper build electrical signal contact bonding pads and the upper build dummy contact bonding pad.

3. The structure of claim 2, further comprising:
at least two upper build electrical signal contact vias, located within the upper build dielectric, and respectively coupled to the at least two upper build electrical signal contact bonding pads;
at least one upper build dummy contact via, located within the upper build dielectric, and coupled to the at least one upper build dummy contact bonding pad, wherein the upper build anti-fuse dielectric is between the upper build ground network and the upper build dummy contact via, and wherein the upper build electrical signal contact bonding pads are coupled to the upper build ground network through the upper build electrical signal contact vias; and
at least two lower build electrical signal contact vias, located within the lower build dielectric, and respectively coupled to the at least two lower build electrical signal contact bonding pads, wherein the lower build anti-fuse dielectric is directly between the lower build ground network and the lower build dummy contact bonding pad, and wherein the lower build electrical signal contact bonding pads are coupled to the lower build ground network through the lower build electrical signal contact vias.

4. The structure of claim 3, wherein the upper and lower build ground networks include a hexagonal mesh.

5. The structure of claim 3, wherein the upper and lower build dielectrics comprise TEOS.

6. The structure of claim 3, wherein the upper and lower build dielectrics comprise SiCN.

7. The structure of claim 3, wherein the upper and lower build dielectrics comprise SiC.

8. The structure of claim 3, wherein the upper and lower build dielectrics comprise SiN.

9. The structure of claim 3, wherein:
the at least two upper build electrical signal contact bonding pads, the at least one upper build dummy contact bonding pad, the at least two upper build electrical signal contact vias, the at least one upper build dummy contact via, the at least two lower build electrical signal contact bonding pads, the at least one lower build dummy contact bonding pad, and the at least two lower build electrical signal contact vias are formed from a first metal; and
the metal from which the lower build ground network is made and the metal from which the upper build ground network is made comprise a same, second metal.

10. The structure of claim 9, wherein the first metal comprises copper.

11. The structure of claim 10, wherein the second metal comprises aluminum.

12. The structure of claim 10, wherein the second metal comprises tin.

13. The structure of claim 10, wherein the second metal comprises indium.

14. The structure of claim 10, wherein the second metal comprises magnesium.

15. The structure of claim 3, wherein the upper build anti-fuse dielectric and the lower build anti-fuse dielectric comprise poly-silicon.

16. The structure of claim 3, wherein the upper build anti-fuse dielectric and the lower build anti-fuse dielectric comprise poly-germanium.

17. The structure of claim 3, wherein the upper build anti-fuse dielectric and the lower build anti-fuse dielectric comprise a one-time material.

18. The structure of claim 3, wherein the upper build anti-fuse dielectric and the lower build anti-fuse dielectric comprise a reusable material.

19. The structure of claim 3, wherein the at least two upper build electrical signal contact vias and the at least two lower build electrical signal contact vias have a pitch of less than 2 micrometers (μm).

20. A method comprising:
providing a structure including:
an upper semiconductor build having:
an upper build dielectric;
at least two upper build electrical signal contact bonding pads, located within the upper build dielectric, and having exposed upper build electrical signal contact bonding pad surfaces;
at least one upper build dummy contact bonding pad, located within the upper build dielectric, and having an exposed upper build dummy contact bonding pad surface;
an upper build ground network, located within the upper build dielectric, electrically coupled to the at least two upper build electrical signal contact bonding pads; and
an upper build anti-fuse dielectric between the upper build ground network and the upper build dummy contact bonding pad; and
a lower semiconductor build having:
a lower build dielectric;
at least two lower build electrical signal contact bonding pads, located within the lower build dielectric, and having exposed lower build electrical signal contact bonding pad surfaces;
at least one lower build dummy contact bonding pad, located within the lower build dielectric, and having an exposed lower build dummy contact bonding pad surface;
a lower build ground network, located within the lower build dielectric, electrically coupled to the at least two lower build electrical signal contact bonding pads; and
a lower build anti-fuse dielectric between the lower build ground network and the lower build dummy contact bonding pad;
wherein:
the lower build dielectric is hybrid bonded to the upper build dielectric;
the at least two lower build electrical signal contact bonding pads are respectively hybrid bonded to the at least two upper build electrical signal contact bonding pads; and
the at least one lower build dummy contact bonding pad is hybrid bonded to the at least one upper build dummy contact bonding pad;
operating the structure until excess charge builds up in the upper build dielectric and the lower build dielectric to blow the upper and lower build anti-fuse dielectrics; and
conducting the excess charge to ground through the blown upper and lower build anti-fuse dielectrics.
